(19) United States
(12) Patent Application Publication
(10) Pub. No.: US 2024/0284765 A1
(43) Pub. Date: Aug. 22, 2024

(54) LIGHT EMITTING DEVICE INCLUDING ORGANIC FUNCTIONAL LAYER

(71) Applicant: CANON KABUSHIKI KAISHA, Tokyo (JP)

(72) Inventor: YUSUKE FUKUCHI, Oita (JP)

(21) Appl. No.: 18/442,468

(22) Filed: Feb. 15, 2024

(30) Foreign Application Priority Data
Feb. 16, 2023 (JP) 2023-022637

(51) Int. Cl. H10K 59/80; H10K 59/123; H10K 59/131; H10K 102/00; H10K 102/20

(52) U.S. Cl. CPC H10K 59/878; H10K 59/123; H10K 59/131; H10K 59/879; H10K 2102/20; H10K 2102/351

(57) ABSTRACT

A light emitting device includes an organic light emitting element arranged above a substrate and including an anode, an organic functional layer including an organic light emitting layer, and a cathode, a capacitive element including an upper electrode arranged between the substrate and the organic light emitting element so as to reflect light entering from the organic functional layer via the anode, a dielectric layer arranged between the substrate and the upper electrode, and a lower electrode arranged between the substrate and the dielectric layer, and an insulating layer arranged between the capacitive element and the organic light emitting element. The upper electrode is electrically insulated from the anode. A distance between the upper electrode and the organic light emitting layer is adjusted so as to improve efficiency of light extraction from the organic light emitting layer.

### BACKGROUND OF THE INVENTION

### Field of the Invention

The present invention relates to a light emitting device including an organic functional layer.

### Description of the Related Art

Interest in a display device using a self-light emitting element such as an organic light emitting diode (OLED) has increased. In the display device using the OLED, in order to prevent deterioration of image quality caused by characteristic variations of a driving transistor forming a pixel circuit, the threshold of the driving transistor is generally corrected using a capacitive element. As the capacitive element, for example, a Metal-Insulator-Metal (MIM) capacitor buried in a wiring structure connecting the transistor provided on a semiconductor substrate and various kinds of signal lines and the like can be used. In recent years, in the display device, the pixel pitch decreases as the resolution increases, and the wiring density increases accordingly. Therefore, the arrangement position and size of the MIM capacitor are readily influenced by the position of a via connecting wiring patterns arranged in different layers and the layout of the wiring patterns, and it becomes difficult to form a sufficient MIM capacity. Japanese Patent Laid-Open No. 2009-200336 describes a self-light emitting type display device in which the anode electrode of an organic light emitting diode is caused to also function as the upper electrode of a capacitive element.

In the display device described in Japanese Patent Laid-Open No. 2009-200336, since the anode electrode of the organic light emitting diode is caused to function as the upper electrode of the capacitive element, independent potentials cannot be respectively applied to the anode electrode and the upper electrode.

### SUMMARY OF THE INVENTION

The present invention provides a technique advantageous in applying different potentials to the anode of an organic light emitting element and the electrode of a capacitive element, respectively, and increasing the capacitance value of the capacitive element.

One of aspects of the present invention provides a light emitting device comprising: an organic light emitting element arranged above a substrate and including an anode, an organic functional layer including an organic light emitting layer, and a cathode; a capacitive element including an upper electrode arranged between the substrate and the organic light emitting element so as to reflect light entering from the organic functional layer via the anode, a dielectric layer arranged between the substrate and the upper electrode, and a lower electrode arranged between the substrate and the dielectric layer; and an insulating layer arranged between the capacitive element and the organic light emitting element, wherein the upper electrode is electrically insulated from the anode, and a distance between the upper electrode and the organic light emitting layer is adjusted so as to improve efficiency of light extraction from the organic light emitting layer.

Further features of the present invention will become apparent from the following description of exemplary embodiments with reference to the attached drawings.

### BRIEF DESCRIPTION OF THE DRAWINGS

FIG. 1 is a view exemplarily showing the arrangement of a light emitting device according to an embodiment;

FIG. 2 is a schematic sectional view showing the structure of a portion of the light emitting device according to the embodiment;

FIG. 3 shows schematic sectional views exemplarily showing a method of manufacturing the light emitting device according to the embodiment;

FIG. 4 shows schematic sectional views exemplarily showing the method of manufacturing the light emitting device according to the embodiment;

FIG. 5 shows schematic sectional views exemplarily showing the method of manufacturing the light emitting device according to the embodiment;

FIGS. 6A to 6C are schematic plan views each showing the structure of a portion of the light emitting device according to the embodiment;

FIGS. 7A and 7B are views each exemplarily showing the circuit arrangement of a pixel of the light emitting device according to the embodiment;

FIG. 8 is an exploded perspective view showing an example of an assembly incorporating the light emitting device;

FIGS. 9A and 9B are exploded perspective views showing two examples of the assembly incorporating the light emitting device;

FIGS. 10A and 10B are views showing two examples of the assembly incorporating the light emitting device;

FIGS. 11A and 11B are views showing two examples of the assembly incorporating the light emitting device; and

FIGS. 12A and 12B are views showing two examples of the assembly incorporating the light emitting device.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

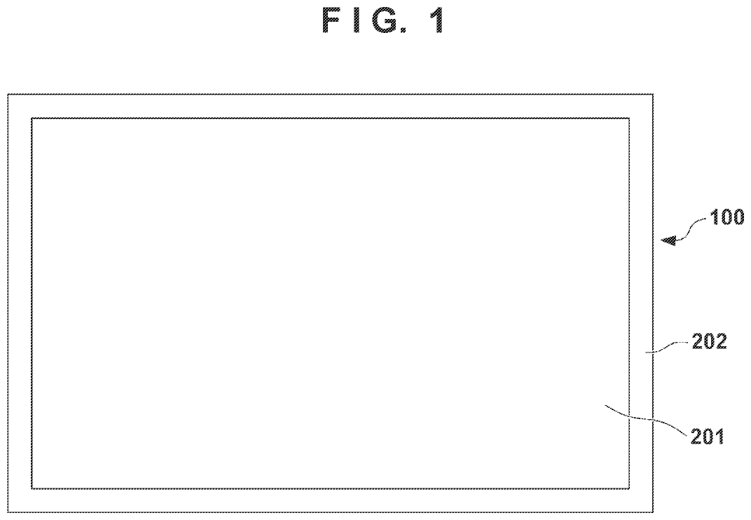

FIG. 1 schematically shows the arrangement of a light emitting device 100 according to an embodiment of the present disclosure. The light emitting device 100 can be formed as, for example, a display device, and may be formed as, for example, a surface light emitting device or a light emitting device including a plurality of light emitting elements. The light emitting device 100 can include, for example, a display region 201 in which a plurality of pixels (in other words, a plurality of light emitting elements) are arranged in a two-dimensional array, and a peripheral circuit region 202 in which a driving circuit for driving the plurality of pixels in the display region 201 are arranged. For example, the driving circuit can supply a pixel signal to each of the plurality of pixels in the display region 201. The light emitting device 100 can be configured to display an image such as a still image or a moving image in the display region 201. The image may be a monochrome image or a full color image. When the image or light intensity distribution displayed or formed in the display region 201 is used for illumination purpose, the light emitting device 100 can be understood as an illumination device.

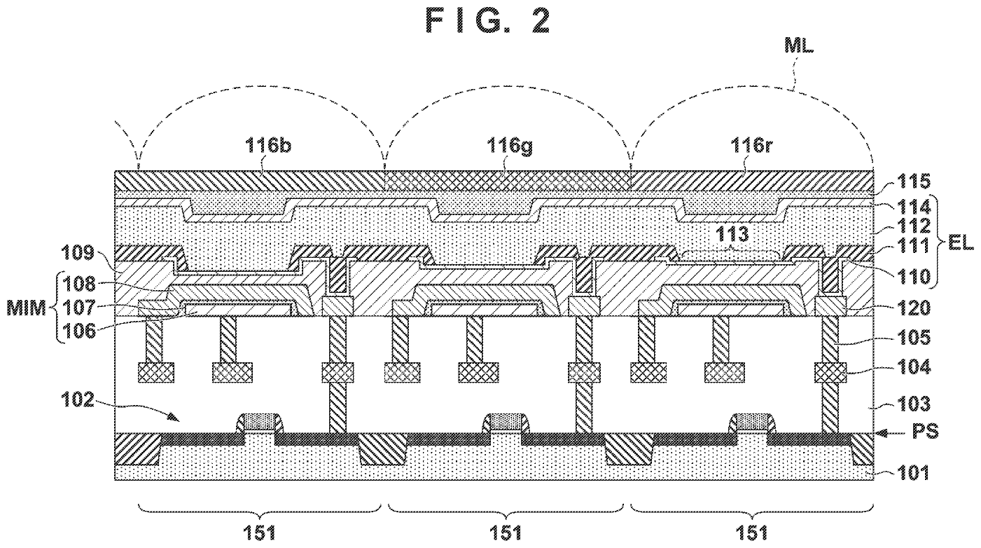

FIG. 2 schematically shows the sectional structure including three pixels 151 of the plurality of pixels 151 arranged in the display region 201. Each pixel 151 can include an organic light emitting element EL including an organic functional layer 112. The organic functional layer 112 can include a light emitting layer containing a self-light emitting material such as an OLED material. In the display region 201, the plurality of pixels 151, which display different colors, can be arranged. In the following description, to indicate a specific pixel, an alphabetical suffix is added at the end of a reference numeral, like a pixel 151b, and to indicate an arbitrary pixel, it will simply be expressed as the pixel “151”. This also applies to other constituent elements.

The light emitting device 100 includes a substrate 101 including a principal surface PS. The substrate 101 is, for example, a base using a semiconductor material such as silicon. A plurality of elements, such as a transistor 102 configured to control light emission (for example, the luminance, the light emission time, and the like) in each pixel 151, can be arranged on the principal surface PS of the substrate 101. An interlayer insulating layer 103 can be arranged above the principal surface PS of the substrate 101 so as to cover the plurality of elements such as the transistor 102. As the material of the interlayer insulating layer 103, for example, an insulating material such as silicon dioxide (SiO₂) can be selected. In the interlayer insulating layer 103, a wiring layer 104 including a conductive pattern can be arranged. As the material of the conductive pattern in the wiring layer 104, for example, an aluminum copper alloy or the like is used.

In the arrangement shown in FIG. 2, only one wiring layer 104 is arranged in the interlayer insulating layer 103. However, the present invention is not limited to this, and two or more wiring layers 104 may be arranged in the interlayer insulating layer 103. Each of electrodes (terminals) of an element, such as the source, drain, and gate of the transistor 102, can be electrically connected to the conductive pattern in the wiring layer 104 by a conductive plug 105. Further, the conductive pattern in the wiring layer 104 and an element arranged above the interlayer insulating layer 103 can be electrically connected by another conductive plug 105. When two or more wiring layers 104 are stacked, the conductive plug 105 can also be arranged to electrically connect the two or more wiring layers 104. The conductive plug 105 can be formed of, for example, tungsten (W) including a barrier metal layer such as titanium/titanium nitride (Ti/TiN). The wiring layer 104 and the conductive plug 105 may be formed separately, or may be formed integrally by a copper wiring member by using a dual damascene method.

A capacitive element MIM having an MIM structure is arranged above the interlayer insulating layer 103. The capacitive element MIM can include a lower electrode 106 electrically connected to the conductive plug 105, a dielectric layer 107, and an upper electrode 108 electrically connected to another conductive plug 105. It may be understood that the upper electrode 108 is arranged between the substrate 101 and the organic light emitting element EL, the dielectric layer 107 is arranged between the substrate 101 and the upper electrode 108, and the lower electrode 106 is arranged between the substrate 101 and the dielectric layer 107. One of the upper electrode 108 and the lower electrode 106 can be electrically connected to the gate of the transistor 102. In an example, the maximum thickness of the upper electrode 108 is larger than the maximum thickness of the lower electrode 106.

The lower electrode 106 can be formed of, for example, titanium nitride (TiN) or the like. The dielectric layer 107 can be formed of the same material as the interlayer insulating layer 103, for example, an insulating material such as silicon dioxide (SiO₂). Alternatively, the dielectric layer 107 may be formed of an insulating material having a higher dielectric constant, such as silicon nitride, hafnium oxide, aluminum oxide, or zirconium oxide. Alternatively, the dielectric layer 107 may have a structure in which two or more films are stacked.

The upper electrode layer where the upper electrode 108 is arranged can include, in addition to the upper electrode 108 as a constituent element of the capacitive element MIM of the MIM structure, a conductive pattern for wiring, for example, a connection pattern 120 to be described later. The connection pattern 120 is electrically insulated from the connection pattern 120. The upper electrode 108 can also function as a reflective layer that reflects light generated in the organic functional layer 112 upward (in the direction from the principal surface PS of the substrate 101 toward the organic functional layer 112). That is, the upper electrode 108 is arranged so as to reflect light entering from the organic functional layer 112 via the anode 110. Hence, the upper electrode 108 can be formed of, for example, pure aluminum with a high reflectance, an aluminum alloy such as an aluminum copper alloy, or the like. In the arrangement as described above, the conductive layer arranged above the wiring layer 104 is used as the reflective layer and the upper electrode 108 of the capacitive element MIM. To arrange a large-area capacitive element without being influenced by the arrangement of the conductive pattern for wiring and the like, this embodiment is more advantageous than the conventional method which buries the MIM capacitive element in the interlayer insulating film.

An optical adjustment layer 109 can be arranged above the upper electrode 108. The optical adjustment layer 109 can be formed by an insulating layer. With the structure in which light generated in the organic functional layer 112 and reaching the upper electrode 108 via the optical adjustment layer 109 is reflected by the upper electrode 108, it is possible to cause light of a specific wavelength band to resonate. For example, when the light emitting device 100 is configured as a display device that displays three colors of R, G, and B, the thickness of at least a part of the optical adjustment layer 109 can be adjusted so that light of the wavelength of each color resonates between the organic functional layer 112 and the upper surface of the upper electrode 108. The thickness of the optical adjustment layer 109 formed by the insulating layer can be, for example, in a range of 10 nm (inclusive) to 250 nm (inclusive). In other words, the distance between the upper electrode 108 and the organic light emitting layer is adjusted so as to improve the efficiency of light extraction from the organic light emitting layer.

The organic light emitting element EL can be arranged on the optical adjustment layer 109. The organic light emitting element EL can include an anode (transparent lower electrode) 110, the organic functional layer 112 including the organic light emitting layer, and a cathode (transparent upper electrode) 114. The organic functional layer 112 can be arranged between the cathode 114 and the substrate 101 (or the capacitive element MIM), and the anode 110 can be arranged between the organic functional layer 112 and the substrate 101 (or the capacitive element MIM). The anode 110 is electrically connected to the drain of the transistor 102 via a conductive path, and can be driven by the transistor 102. The conductive path can include, for example, the conductive plug 105, the conductive pattern arranged in the wiring layer 104, and a connection pattern 120 arranged in the upper electrode layer in which the upper electrode 108 is arranged. The anode 110 is an electrode that supplies, to the organic functional layer 112, a current for causing the light emitting layer of the organic functional layer 112 to emit light. The anode 110 can be formed of, for example, a transparent material such as indium tin oxide (ITO) or indium zinc oxide (IZO).

The peripheral portion of the anode 110 can be covered with an insulating layer 111 including an opening 113 that exposes the central portion of the anode 110. In an orthogonal projection with respect to the principal surface PS of the substrate 101, the opening 113 overlaps the upper electrode 108. In the orthogonal projection, the opening 113 overlaps the lower electrode 106. Further, in the orthogonal projection, the opening 113 can be configured to fit within the region of the upper electrode 108. Furthermore, in the orthogonal projection, the opening 113 can be configured to fit within the region of the lower electrode 106. The anode 110 contacts the organic functional layer 112 in the opening 113.

The cathode 114 is arranged above the organic functional layer 112. The cathode 114 can be formed of, for example, a transparent material such as indium tin oxide (ITO) or indium zinc oxide (IZO). As exemplarily shown in FIG. 2, the organic functional layer 112 and the cathode 114 may be shared by the plurality of pixels 151. For example, the organic functional layer 112 and the cathode 114 may integrally be formed over the entire display region 201.

A sealing layer 115 can be arranged above the cathode 114. The sealing layer 115 can be formed of, for example, a material such as silicon nitride. The sealing layer 115 seals respective constituent elements such as the transistor 102 formed in the substrate 101 and the organic functional layer 112, and suppresses invasion of outer air and water into them.

Color filters 116 can be arranged above the sealing layer 115. In an example, the light emitting layer included in the organic functional layer 112 generate white light, and the color filters 116 convert the white light into a plurality of colors. In an example, a color filter 116b that transmits blue light is provided in the pixel 151 that generates blue light, a color filter 116g that transmits green light is provided in the pixel that generates green light, and a color filter 116r that transmits red light is provided in the pixel that generates red light. A microlens ML may be arranged on the color filter 116.

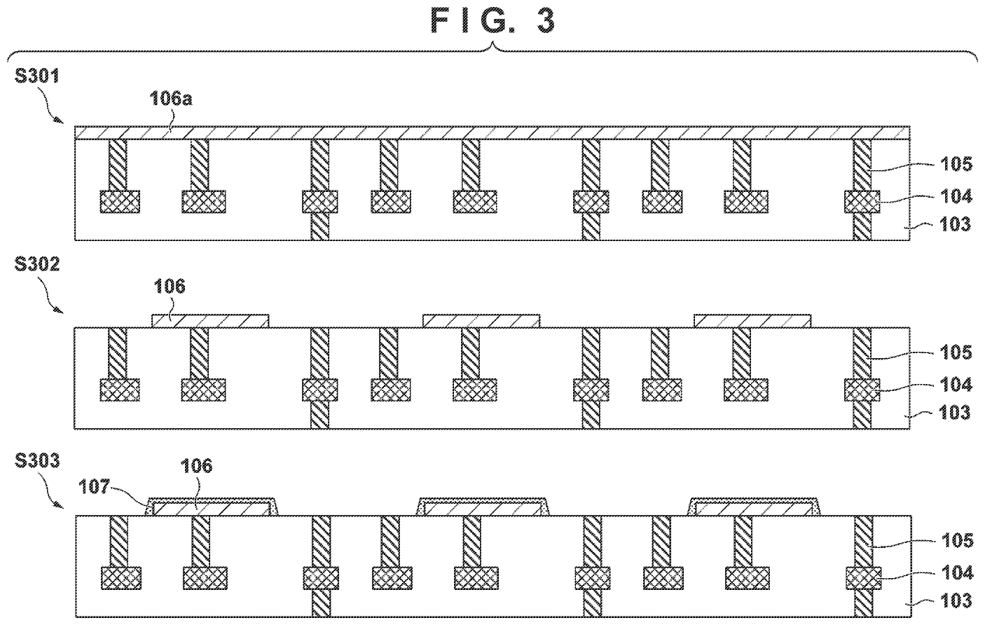

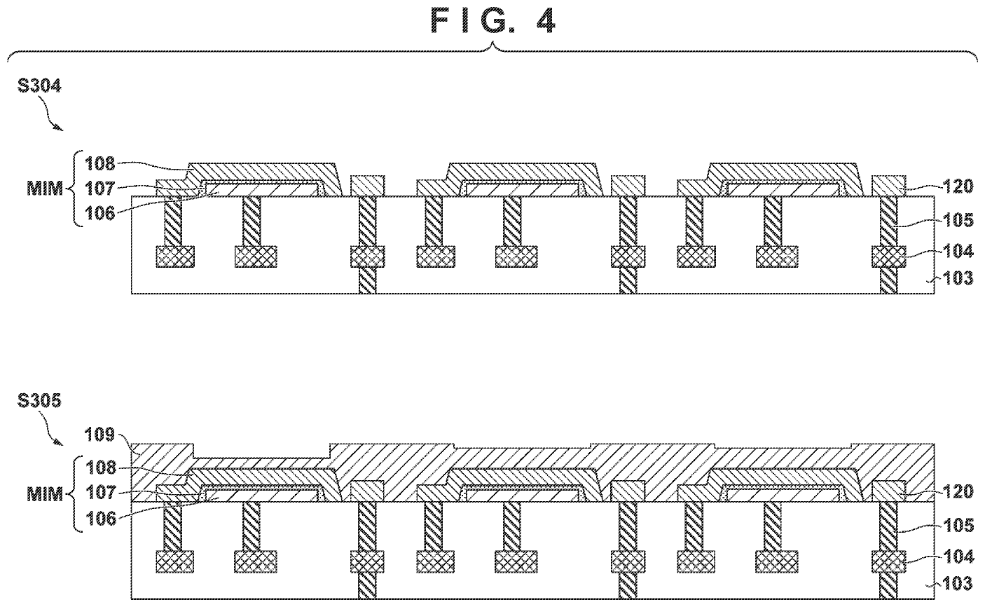

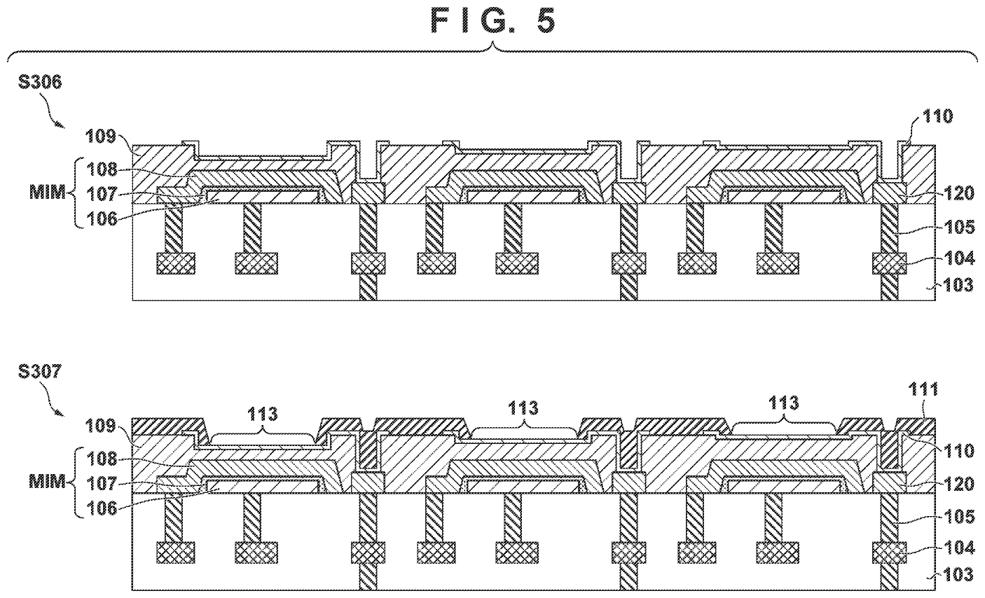

Next, with reference to FIGS. 3 to 5, a method of manufacturing the light emitting device 100 will be exemplarily described. In FIGS. 3 to 5, the constituent elements below the lower electrode 106 (in the part from the lower electrode 106 to the substrate 101) may be similar to those in FIG. 2. Hence, a part of the interlayer insulating layer 103 and the substrate 101 are not illustrated.
In step S301, a lower electrode layer 106a is formed on the interlayer insulating layer 103 so as to cover the interlayer insulating layer 103. As the lower electrode layer 106a, for example, a titanium nitride (TiN) film can be formed using a deposition method such as a sputtering method.
Then, in step S302, by patterning the lower electrode layer 106a using a patterning method including a photolithography step, a dry etching step, and the like, the lower electrode 106 of the capacitive element MIM for each pixel can be formed.
Then, in step S303, by using a deposition method such as a CVD method, a dielectric film for forming the dielectric layer, for example, a silicon oxide film can be formed so as to cover the interlayer insulating layer 103 and the lower electrode 106. Further, by patterning the dielectric film using a patterning method including a photolithography step, a dry etching step, and the like, the dielectric layer 107 is formed.
Then, in step S304, by using a deposition method such as a sputtering method, an upper electrode layer can be formed so as to cover the interlayer insulating layer 103 and the dielectric layer 107. The upper electrode layer can be formed of, for example, aluminum with a high optical reflectance, an aluminum alloy, or the like. Further, by patterning the upper electrode layer using a patterning method including a photolithography step, a dry etching step, and the like, the upper electrode 108 and the connection pattern 120 can be formed.
Then, in step S305, the optical adjustment layer 109, for example, a silicon oxide layer can be formed by using a deposition method such as a CVD method so as to cover the interlayer insulating layer 103 and the upper electrode 108. Further, by a method including a photolithography step, a dry etching step, and the like, the thickness of the portion of the optical adjustment layer 109 located above the upper electrode 108 can be adjusted to a target thickness. At this time, by controlling the residual film thickness of the optical adjustment layer 109 in accordance with the display color of the pixel, it is possible to cause light of the wavelength of each color to resonate.
Then, in step S306, a through hole can be formed in the optical adjustment layer 109 by a patterning method including a photolithography step, a dry etching step, and the like such that the through hole extends through a part of the optical adjustment layer 109 and reaches the connection pattern 120. Further, a transparent electrode layer, for example, an ITO film can be formed by using a deposition method such as a sputtering method so as to cover the optical adjustment layer 109 and the through hole. The transparent electrode layer can be formed so as to be electrically connected to the connection pattern 120 through the through hole. Further, by patterning the transparent electrode layer using a patterning method including a photolithography step, a dry etching step, and the like, the anode 110 electrically connected to the contact pattern 120 can be formed.
Then, in step S307, the insulating layer 111 can be formed so as to cover the optical adjustment layer 109 and the anode 110. The insulating layer 111 can be formed of, for example, silicon dioxide or the like by using a deposition method such as a CVD method. Further, by patterning the insulating layer 111 using a patterning method including a photolithography step, a dry etching step, and the like, the opening 113 can be formed in the insulating layer 111. The dry etching step can be performed under a condition that the etching rate of the insulating layer 111 is sufficiently higher than the etching rate of the anode 110. In this case, the anode 110 functions as an etching stopper. The insulating layer 111 can be etched such that the portion facing the opening 113 has a tapered shape.

After the opening 113 is formed, the organic functional layer 112 including the light emitting layer can be formed by a vacuum deposition method using a vapor deposition mask so as to contact the anode 110 (the portion thereof exposed by the opening 113). Further, the cathode 114, the sealing layer 115, the color filters 116 can be sequentially formed on the organic functional layer 112. With the steps described above, the light emitting device 100 can be formed.

In this embodiment, since the upper electrode 108 of the capacitive element MIM is located above the wiring layer 104 where the main wiring pattern is arranged, the arrangement of the conductive pattern has little influence on the upper electrode 108. Therefore, this embodiment is advantageous in increasing the capacitance of the capacitive element MIM. Further, according to this embodiment, it is possible to connect different nodes to the anode 110 of the organic light emitting element EL and the upper electrode 108 of the capacitive element MIM, respectively. This improves the degree of freedom in design of the circuit forming the pixel.

In addition, since the upper electrode 108 has a function of reflecting light generated in the organic functional layer 112, an effect of increasing the light emission efficiency of the light emitting device 100 can be obtained. Further, owing to the optical adjustment layer 109 adjusted to the thickness that causes light generated in the organic functional layer 112 to resonate by reflection by the upper electrode 108, an effect of increasing the light emission efficiency of light of a specific wavelength band is obtained.

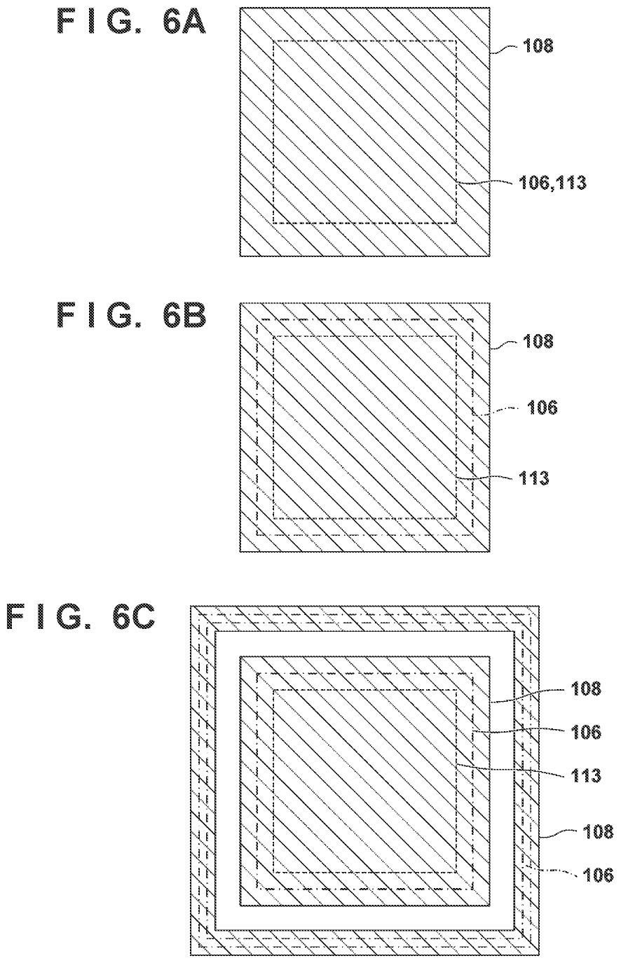

Here, with reference to FIGS. 6A to 6C, preferable examples of the geometric relationship between the capacitive element MIM and the opening 113 will be described. Each of FIGS. 6A to 6C is a view showing the orthogonal projection with respect to the principal surface PS of the substrate 101. Each of these views may be understood as a view showing a planar view. The upper electrode 108 of the capacitive element MIM can be configured to have a function of reflecting light generated in the organic functional layer 112. The upper electrode 108 of the capacitive element MIM can be formed so as to cover the upper surface and side surface of the lower electrode 106 of the capacitive element MIM. In this case, the upper surface of the upper electrode 108 is not flat but can have a step in a portion close to the outer edge of the upper electrode 108 (or the portion above the outer edge of the lower electrode 106). If this step exists inside the opening 113, light generated in the organic functional layer 112 may be reflected in an unintended direction, resulting in decreased color purity and color mixing. Therefore, as exemplarily shown in FIGS. 6A and 6B, in the orthogonal projection with respect to the principal surface PS of the substrate 101, the opening 113 preferably fits within the region of the lower electrode 106. Further, in the orthogonal projection with respect to the principal surface PS of the substrate 101, the outer edge of the opening 113 is preferably arranged inside the outer edge of the lower electrode 106. FIG. 6A schematically shows an example in which the outer edge of the opening 113 matches the outer edge of the lower electrode 106 in the orthogonal projection. FIG. 6B schematically shows an example in which the outer edge of the opening 113 is arranged inside the outer edge of the lower electrode 106 in the orthogonal projection.

A plurality of the capacitive elements MIM may be arranged in one pixel. FIG. 6C shows an example in which two capacitive elements MIM are arranged in one pixel. Also in such the case, in the orthogonal projection with respect to the principal surface PS of the substrate 101, the opening 113 preferably fits within the region of the lower electrode 106. The shape of the opening 113 is not limited to a quadrangle or a polygon as exemplarily shown in FIGS. 6A to 6C, and may be, for example, a circle or an oval. The microlens ML may be arranged above the color filter 116 so the light emission efficiency does not decrease even if the area of the opening 113 is reduced.

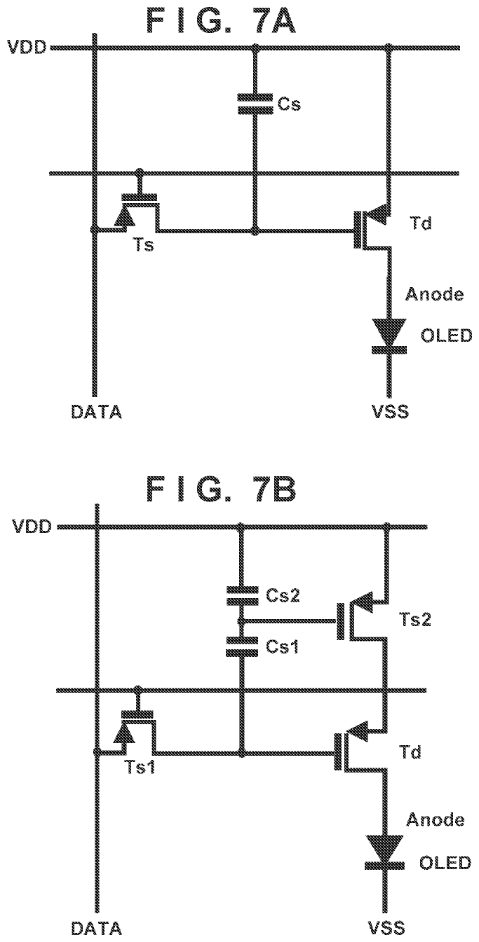

FIG. 7A shows an example of the circuit arrangement of the pixel 151. In the example shown in FIG. 7A, the pixel 151 has 2Tr1C arrangement including two transistors Ts and Td and one capacitive element Cs. More specifically, the pixel 151 includes the driving transistor Td, the selection transistor Ts, and the capacitive element Cs for correcting the threshold of the driving transistor Td. The driving transistor Td is illustrated as the transistor 102 in FIG. 2, and the capacitive element Cs is illustrated as the capacitive element MIM in FIG. 2. In the example shown in FIG. 7A, the selection transistor Ts is formed by a PMOS, but may be formed by an NMOS.

The driving transistor Td is preferably formed by a PMOS. When the transistor Td is operated as a source follower, the magnitude of the current flowing through the organic light emitting element EL can be controlled. The drain of the driving transistor Td can be electrically connected to the anode 110 of the organic light emitting element EL. The capacitive element Cs can be connected between the gate and source of the driving transistor Td. The capacitive element Cs has a function of receiving a signal voltage from a Data line and holding the voltage of the threshold level of the driving transistor Td, thereby correcting the difference of the threshold of the driving transistor Td which changes for each pixel. The anode of the organic light emitting element EL connected to the drain terminal of the driving transistor Td and the capacitive element Cs are electrically connected to different circuit nodes. Accordingly, it is possible to apply different potentials to the upper electrode of the capacitive element Cs and the anode of the organic light emitting element EL, respectively.

FIG. 7B shows another example of the circuit arrangement of the pixel 151. In the example shown in FIG. 7B, the pixel 151 has 3Tr2C arrangement including three transistors Ts1, Ts2, and Td and two capacitive elements Cs1 and Cs2. The driving transistor Td is illustrated as the transistor 102 in FIG. 2, and each of the capacitive elements Cs1 and Cs2 is illustrated as the capacitive element MIM in FIG. 2.

The arrangement of the pixel is not limited to the examples described above, and may be another arrangement. For example, the pixel can include a reset switch.

Hereinafter, respective constituent elements of the light emitting element will be exemplarily described.

Quartz, glass, a silicon wafer, a resin, a metal, or the like may be used as a substrate. Furthermore, a switching element such as a transistor and a wiring may be provided on the substrate, and an insulating layer may be provided thereon. The insulating layer may be made of any material as long as a contact hole can be formed so that the wiring can be formed between the insulating layer and the lower electrode, the upper electrode, and the anode and insulation from the unconnected wiring can be ensured. For example, a resin such as polyimide, silicon oxide, silicon nitride, or the like can be used.

An insulating layer (pixel isolation layer) for isolating pixels is formed of a silicon nitride (SiN) film, a silicon oxynitride (SiON) film, or a silicon oxide (SiO) film formed using a chemical vapor deposition method (CVD method). In order to increase the resistance in the in-plane direction of the organic compound layer, the organic compound layer, particularly, the hole transport layer is preferably deposited so as to have a small film thickness on the side wall of the pixel isolation layer. More specifically, by increasing the taper angle of the side wall of the pixel isolation layer or the film thickness of the pixel isolation layer to increase vignetting during vapor deposition, the organic compound layer can be deposited so as to have a small film thickness on the side wall of the pixel isolation layer.

On the other hand, it is preferable to adjust the taper angle of the side wall of the pixel isolation layer or the film thickness of the pixel isolation layer to the extent not forming a gap in the protective layer formed on the pixel isolation layer. If no gap is formed in the protective layer, generation of defects in the protective layer can be reduced. Since generation of defects in the protective layer is reduced, a decrease in reliability due to generation of a dark spot or occurrence of a conductive failure of the second electrode can be reduced.

The organic functional layer may be formed by a single layer or a plurality of layers. If the organic functional layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic functional layer is mainly formed from an organic compound but may contain inorganic atoms and an inorganic compound. For example, the organic functional layer may contain copper, lithium, magnesium, aluminum, iridium, platinum, molybdenum, zinc, or the like. The organic compound layer can be arranged between the first and second electrodes, and may be arranged in contact with the first and second electrodes.

A protective layer may be provided on the cathode. For example, by adhering glass provided with a moisture absorbing agent on the cathode, permeation of water or the like into the organic functional layer can be reduced and occurrence of display defects can be reduced. Furthermore, as another embodiment, a passivation film made of silicon nitride or the like may be provided on the cathode to reduce permeation of water or the like into the organic functional layer. For example, the protective layer can be formed by forming the cathode, transferring it to another chamber without breaking the vacuum, and forming a silicon nitride film having a thickness of 2 μm by a CVD method. The protective layer may be provided using an atomic deposition method (ALD method) after forming a film using the CVD method. The material of the film by the ALD method is not limited but can be silicon nitride, silicon oxide, aluminum oxide, or the like. A silicon nitride film may further be formed by the CVD method on the film formed by the ALD method. The film formed by the ALD method may have a film thickness smaller than that of the film formed by the CVD method. More specifically, the film thickness of the film formed by the ALD method may be 50% or less, or 10% or less.

A color filter may be provided on the protective layer. For example, a color filter considering the size of the organic light emitting element may be provided on another substrate, and this substrate may be bonded to the substrate with the organic light emitting element provided thereon. Alternatively, a color filter may be patterned on the above-described protective layer using a photolithography technique. The color filter can be formed from a polymeric material.

A planarizing layer may be provided between the color filter and the protective layer. The planarizing layer is provided to reduce unevenness of the lower layer. The planarizing layer may be called a material resin layer without limiting the purpose of the layer. The planarizing layer can be formed from an organic compound, and can be made of a low-molecular material or a polymeric material. However, a polymetric material is preferable.

The planarizing layers may be provided above and below the color filter, and the same or different materials may be used for them. More specifically, examples of the material include polyvinyl carbazole resin, polycarbonate resin, polyester resin, ABS resin, acrylic resin, polyimide resin, phenol resin, epoxy resin, silicone resin, and urea resin.

The light emitting device can include an optical member such as a microlens on the light emission side. The microlens can be made of acrylic resin, epoxy resin, or the like. The microlens can aim to increase the amount of light extracted from the light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface is preferably arranged on the functional layer side of the first surface. For this arrangement, the microlens is required to be formed on the light emitting device. If the functional layer is an organic layer, it is preferable to avoid a process which produces high temperature in the manufacturing step. In addition, if it is configured to arrange the second surface on the functional layer side of the first surface, all the glass transition temperatures of organic compound forming the organic layer are preferably 100° C. or more, and more preferably 130° C. or more.

The organic functional layer (hole injection layer, hole transport layer, electron blocking layer, light emitting layer, hole blocking layer, electron transport layer, electron injection layer, and the like) can be formed by, for example, a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

The light emitting device may include a pixel circuit connected to the light emitting element. The pixel circuit may be an active matrix circuit that individually controls light emission of a plurality of light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

The light emitting device includes a plurality of pixels. Each pixel includes sub-pixels that emit light components of different colors. The sub-pixels include, for example, R, G, and B emission colors, respectively. In each pixel, a region also called a pixel opening emits light. This region is the same as the first region. The pixel opening can have a size of 5 μm (inclusive) to 15 μm (inclusive). More specifically, the pixel opening can have a size of 11 μm, 9.5 μm, 7.4 μm, 6.4 μm, or the like. A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

The light emitting device according to one aspect of the present invention can be incorporated in various devices. The device incorporating the light emitting device according to one aspect of the present invention can be called an assembly. In addition to the light emitting device according to one aspect of the present invention, the assembly can include a control circuit that controls the light emitting device. The control circuit may be a printed wiring board including a semiconductor chip, may be a semiconductor chip, or may be incorporated into the same chip as the light emitting device. The assembly can function as at least one of a display device, an image capturing device, an illumination device, an image forming device, a moving body, and a wearable device. The illumination device can also include a mode such as a backlight.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer may have a touch panel function. The driving type of the touch panel function may be an infrared type, a capacitance type, a resistive film type, or an electromagnetic induction type, and is not particularly limited. The display device may be used for the display unit of a multifunction printer.

Next, specific examples of the assembly will be described with reference to drawings.

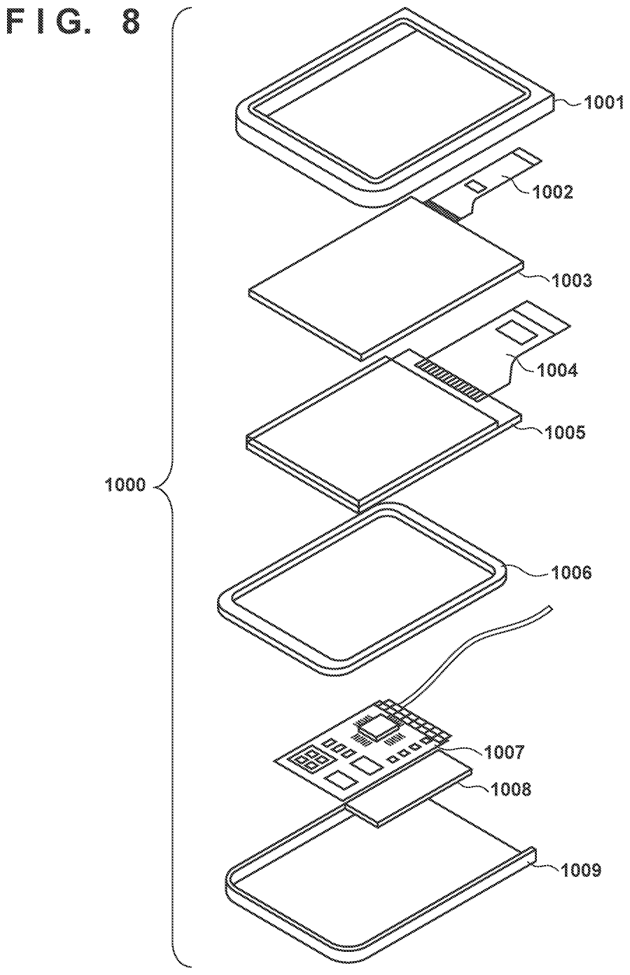

FIG. 8 shows an example of the assembly formed as a display device. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display device is not a portable apparatus. Even when the display device is a portable apparatus, the battery 1008 may be provided at another position.

The display device 1000 can include color filters of red, green, and blue. The color filters of red, green, and blue can be arranged in a delta array. The display device 1000 can also be used for a display unit of a portable terminal. At this time, the display unit can have both a display function and an operation function. Examples of the portable terminal are a portable phone such as a smartphone, a tablet, and a head mounted display.

The display device 1000 can be used for a display unit of an image capturing device including a fixed or detachable optical unit including a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

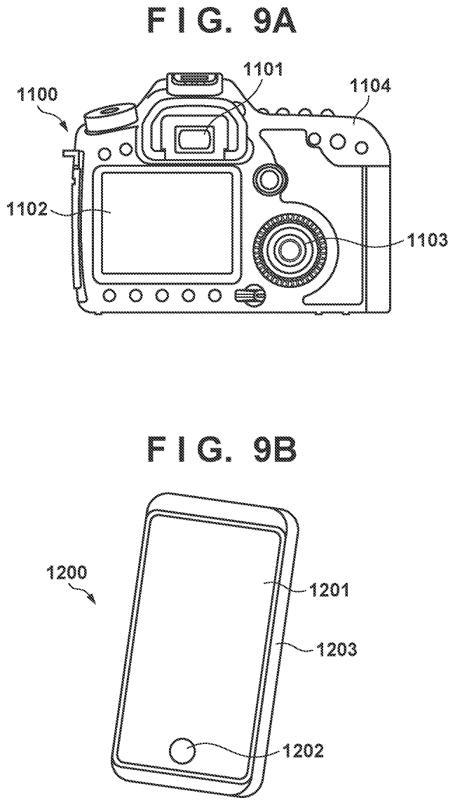

FIG. 9A shows an example of the assembly formed as an image capturing device. An image capturing device 1100 can include a viewfinder 1101, a rear display 1102, an operation unit 1103, and a housing 1104. The viewfinder 1101 may include the light emitting device 100 formed as a display device. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. The display device using the organic light emitting element can be used for the apparatuses that require a high display speed more preferably than for the liquid crystal display device.

The image capturing device 1100 includes an optical unit (not shown). This optical unit includes a plurality of lenses, and forms an image on an image sensor that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 9B shows another example of the assembly formed as an electronic apparatus. An electronic apparatus 1200 includes a display unit 1201, an operation unit 1202, and a housing 1203. The housing 1203 can accommodate a circuit, a printed board including this circuit, a battery, and a communication unit. The operation unit 1202 may be a button or a touch-panel-type reaction unit. The operation unit may also be a biometric authentication unit that performs unlocking or the like by authenticating a fingerprint. The electronic apparatus including the communication unit can also be regarded as a communication apparatus. The electronic apparatus can further have a camera function by including a lens and an image sensor. An image captured by the camera function is displayed on the display unit. Examples of the electronic apparatus are a smartphone and a laptop computer.

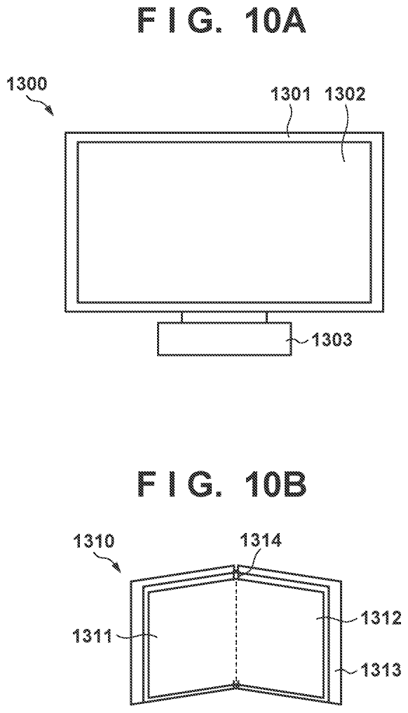

Each of FIGS. 10A and 10B shows an example of the assembly formed as a display device. The example shown in FIG. 10A is preferable as a display device such as a television monitor or a PC monitor. A display device 1300 includes a frame 1301 and a display unit 1302. The light emitting device according to the embodiment may be used in the display unit 1302. The display device 1300 includes a base 1303 that supports the frame 1301 and the display unit 1302. The base 1303 is not limited to the form shown in FIG. 10A. The lower side of the frame 1301 may also function as the base.

In addition, the frame 1301 and the display unit 1302 may be bent. The radius of curvature can be 5,000 mm (inclusive) to 6,000 mm (inclusive).

FIG. 10B shows still another example of the assembly formed as a display device. A display device 1310 shown in FIG. 10B is configured to be foldable, that is, the display device 1310 is a so-called foldable display device. The display device 1310 includes a first display unit 1311, a second display unit 1312, a housing 1313, and a bending point 1314. Each of the first display unit 1311 and the second display unit 1312 may include the light emitting device according to the embodiment. The first display unit 1311 and the second display unit 1312 may be one seamless display device. The first display unit 1311 and the second display unit 1312 can be divided by the bending point. The first display unit 1311 and the second display unit 1312 can display different images, and can also display one image together.

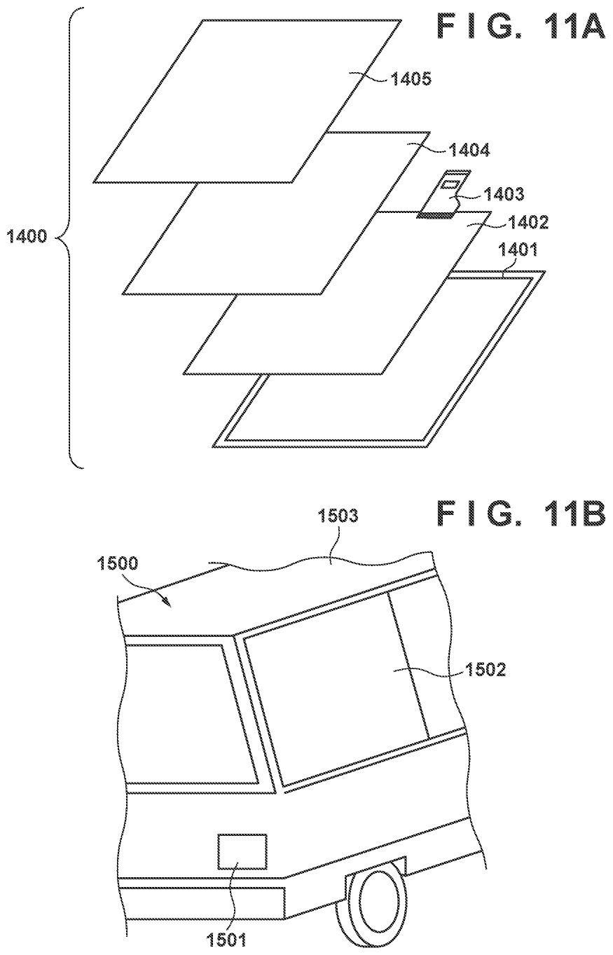

FIG. 11A shows an example of the assembly formed as an illumination device. An illumination device 1400 can include a housing 1401, a light source 1402, a circuit board 1403, an optical film 1404, and a light-diffusing unit 1405. The light source can include the light emitting device 100. The optical filter can be a filter that improves the color rendering of the light source. When performing lighting-up or the like, the light-diffusing unit can throw the light of the light source over a broad range by effectively diffusing the light. The optical filter and the light-diffusing unit can be provided on the illumination light emission side. The illumination device can also include a cover on the outermost portion, as needed.

The illumination device is, for example, a device for illuminating the interior of the room. The illumination device may emit white light, natural white light, or light of any color from blue to red. The illumination device can also include a light control circuit for controlling these light components. The illumination device can also include the organic light emitting element according to the present invention and a power supply circuit connected to the organic light emitting element. The power supply circuit is a circuit for converting an AC voltage into a DC voltage. White has a color temperature of 4,200 K, and natural white has a color temperature of 5,000 K. The illumination device may also include a color filter.

In addition, the illumination device according to this embodiment may include a heat radiation unit. The heat radiation unit radiates the internal heat of the device to the outside of the device, and examples are a metal having a high specific heat and liquid silicon.

FIG. 11B is a schematic view of an automobile as an example of the assembly formed as a moving body. The automobile has a taillight as an example of the lighting appliance. An automobile 1500 has a taillight 1501, and can have a form in which the taillight is turned on when performing a braking operation or the like.

The taillight 1501 can include the light emitting device 100. The taillight can include a protection member for protecting the organic EL element. The material of the protection member is not limited as long as the material is a transparent material with a strength that is high to some extent, and is preferably polycarbonate. A furandicarboxylic acid derivative, an acrylonitrile derivative, or the like may be mixed in polycarbonate.

The automobile 1500 can include a vehicle body 1503, and a window 1502 attached to the vehicle body 1503. This window may be a window for checking the front and back of the automobile, and can also be a transparent display. This transparent display can include the organic light emitting element according to the embodiment. In this case, the constituent materials of the electrodes and the like of the organic light emitting element are formed by transparent members.

The moving body according to this embodiment can be a ship, an airplane, a drone, or the like. The moving body can include a main body and a lighting appliance provided on the main body. The lighting appliance can emit light for making a notification of the position of the main body. The lighting appliance includes the organic light emitting element according to the embodiment.

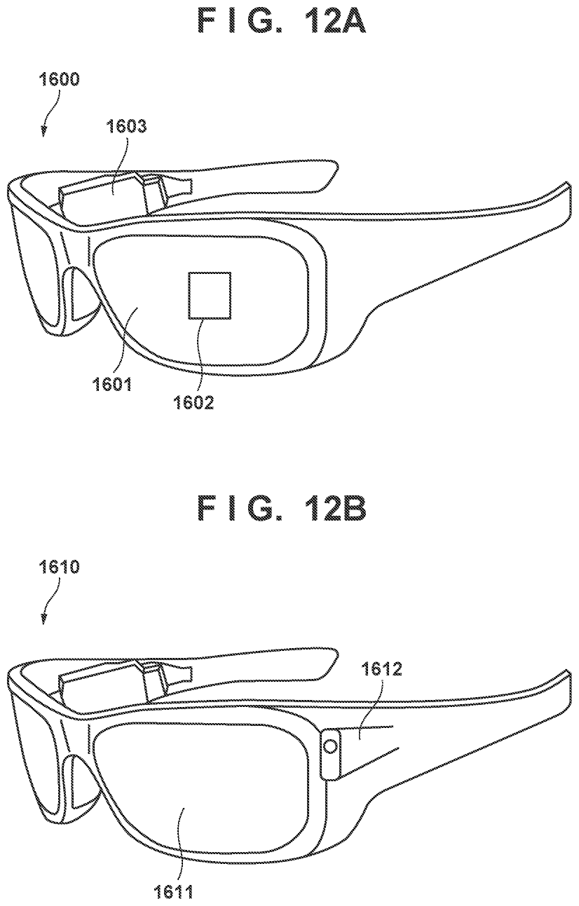

Each of FIGS. 12A and 12B shows an example of the assembly formed as a wearable device. The light emitting device 100 formed as the display device can be applied to a system that can be worn as a wearable device such as smartglasses, an HMD, or a smart contact lens. An image capturing display device used in such an application example includes an image capturing device capable of photoelectrically converting visible light and a display device capable of emitting visible light.

Glasses 1600 (smartglasses) according to one application example will be described with reference to FIG. 12A. An image capturing device 1602 such as a CMOS sensor or an SPAD is provided on the front surface side of a lens 1601 of the glasses 1600. In addition, the light emitting device 100 formed as the display device can be provided on the back surface side of the lens 1601.

The glasses 1600 further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 12B. The glasses 1610 includes a control device 1612. An image capturing device corresponding to the image capturing device 1602 and a display device are mounted on the control device 1612. An optical system configured to project light emitted from the display device in the control device 1612 is formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention may include an image capturing device including a light receiving element, and a displayed image on the display device may be controlled based on the line-of-sight information of the user from the image capturing device.

More specifically, the display device decides a first display region at which the user is gazing and a second display region other than the first display region based on the line-of-sight information. The first display region and the second display region may be decided by the control device of the display device, or those decided by an external control device may be received. In the display region of the display device, the display resolution of the first display region may be controlled to be higher than the display resolution of the second display region. That is, the resolution of the second display region may be lower than that of the first display region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first display region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-022637, filed Feb. 16, 2023 which is hereby incorporated by reference herein in its entirety.

What is claimed is:

1. A light emitting device comprising:
an organic light emitting element arranged above a substrate and including an anode, an organic functional layer including an organic light emitting layer, and a cathode;
a capacitive element including an upper electrode arranged between the substrate and the organic light emitting element so as to reflect light entering from the organic functional layer via the anode, a dielectric layer arranged between the substrate and the upper electrode, and a lower electrode arranged between the substrate and the dielectric layer; and
an insulating layer arranged between the capacitive element and the organic light emitting element,
wherein the upper electrode is electrically insulated from the anode, and
a distance between the upper electrode and the organic light emitting layer is adjusted so as to improve efficiency of light extraction from the organic light emitting layer.

2. The device according to claim 1, wherein
the anode is arranged between the substrate and the organic functional layer.

3. The device according to claim 1, wherein
the insulating layer has a thickness in a range of not less than 10 nm and not more than 250 nm.

4. The device according to claim 1, further comprising a transistor arranged on the substrate and configured to drive the organic light emitting element,
wherein one of the upper electrode and the lower electrode of the capacitive element is electrically connected to a gate of the transistor.

5. The device according to claim 1, wherein
a peripheral portion of the anode is covered with an insulating layer including an opening configured to expose a central portion of the anode, and
in an orthogonal projection with respect to a principal surface of the substrate, the opening overlaps the upper electrode.

6. The device according to claim 5, wherein
in the orthogonal projection, the opening fits within a region of the lower electrode.

7. The device according to claim 6, wherein
in the orthogonal projection, an outer edge of the opening is arranged inside an outer edge of the lower electrode.

8. The device according to claim 1, wherein
the lower electrode contains titanium nitride.

9. The device according to claim 1, wherein
the upper electrode contains one of aluminum and an aluminum alloy.

10. The device according to claim 1, wherein
a maximum thickness of the upper electrode is larger than a maximum thickness of the lower electrode.

11. The device according to claim 1, wherein
a conductive layer including a conductive pattern is arranged between the substrate and a layer including the lower electrode.

12. The device according to claim 1, wherein
a layer including the upper electrode includes a connection pattern configured to electrically connect an electrode of a transistor arranged in the substrate to the anode, and
the connection pattern is electrically insulated from the upper electrode.

13. The device according to claim 1, further comprising a microlens arranged above the organic light emitting element.

14. An assembly comprising:
a light emitting device defined in claim 1; and
a control circuit configured to control the light emitting device.

15. An assembly according to claim 14, wherein
the assembly functions as at least one of a display device, an image capturing device, an illumination device, an image forming device, a moving body, and a wearable device.
